(19) United States
(12) Patent Application Publication
(10) Pub. No.: US 2025/0146928 A1
(43) Pub. Date: May 8, 2025

(54) DETECTION DEVICE

(71) Applicant: Japan Display Inc., Tokyo (JP)

(72) Inventors: Tomoyuki ISHIHARA, Tokyo (JP); Akihiko FUJISAWA, Tokyo (JP); Chikyu NAKAOKA, Tokyo (JP); Tsutomu HARADA, Tokyo (JP); Kaoru ITO, Tokyo (JP); Norio MAMBA, Tokyo (JP)

(21) Appl. No.: 19/018,010

(22) Filed: Jan. 13, 2025

Related U.S. Application Data
(63) Continuation of application No. PCT/JP2023/024787, filed on Jul. 4, 2023.

(30) Foreign Application Priority Data
Jul. 15, 2022 (JP) 2022-113828

(51) Int. Cl. G01N 21/17

(52) U.S. Cl. CPC G01N 21/17; G01N 2021/1765; G01N 2201/0626; G01N 2201/0633; G01N 2201/067

(57) ABSTRACT

According to an aspect, a detection device includes: a plurality of photodiodes provided on a substrate; a plurality of light emitters arranged so as to face the photodiodes; and a collimating lens that is located between the photodiodes and the light emitters and is configured to emit parallel light toward the photodiodes. At least one of the light emitters is configured to be brought into a lit state and other of the light emitters are configured to be brought into an unlit state. The collimating lens is configured to emit the parallel light at a different emission angle depending on a position of the light emitter in the lit state.

### CROSS-REFERENCE TO RELATED APPLICATION

This application claims the benefit of priority from Japanese Patent Application No. 2022-113828 filed on Jul. 15, 2022 and International Patent Application No. PCT/JP2023/024787 filed on Jul. 4, 2023, the entire contents of which are incorporated herein by reference.

### BACKGROUND

### 1. Technical Field

What is disclosed herein relates to a detection device.

### 2. Description of the Related Art

International Patent Application Publication No. WO2012/060303 describes a display device with optical sensors that includes an active matrix substrate including a plurality of pixels and a plurality of optical sensors provided in a pixel area. In the display device with optical sensors of WO2012/060303, the pixels and the optical sensors are provided on the same substrate.

International Patent Application Publication No. WO2018/203373 describes a mounting device that performs super-resolution processing to generate an image having a higher resolution than that of a captured image. Yuji Nakazawa, Takashi Komatsu & Takahiro Saito: “Sub-pixel registration for super high resolution image acquisition based on temporal integration”, ICIAP 1995: Image Analysis and Processing, pp 387-392 (hereinafter referred to as “Yuji Nakazawa et al.”) and Shin Aoki: “Super Resolution Processing by Plural Number of Lower Resolution Images”, Ricoh Technical Report No. 24, November 1998 (hereinafter referred to as “Shin Aoki”) each describe a technology of the super-resolution processing to obtain high-resolution data having a higher resolution than that of a sensor.

In the display device with optical sensors of WO2012/060303, the arrangement pitch of the optical sensors is larger than that of the pixels, so that the resolution of the optical sensors is lower than that of the pixels. Detection devices provided with such optical sensors are required to increase the resolution of detection. WO2018/203373, Yuji Nakazawa et al., and Shin Aoki each do not describe a specific configuration for applying the super-resolution processing to a detection device provided with optical sensors.

For the foregoing reasons, there is a need for a detection device capable of obtaining images having a resolution higher than a sensor resolution.

### SUMMARY

According to an aspect, a detection device includes: a plurality of photodiodes provided on a substrate; a plurality of light emitters arranged so as to face the photodiodes; and a collimating lens that is located between the photodiodes and the light emitters and is configured to emit parallel light toward the photodiodes. At least one of the light emitters is configured to be brought into a lit state and other of the light emitters are configured to be brought into an unlit state. The collimating lens is configured to emit the parallel light at a different emission angle depending on a position of the light emitter in the lit state.

### BRIEF DESCRIPTION OF THE DRAWINGS

FIG. 1 is a sectional view schematically illustrating a detection device according to a first embodiment;

FIG. 2 is a sectional view schematically illustrating the detection device in a detection period different from that of FIG. 1;

FIG. 3 is a block diagram illustrating a configuration example of the detection device according to the first embodiment;

FIG. 4 is a block diagram illustrating a configuration example of a detection control circuit according to the first embodiment;

FIG. 5 is a circuit diagram illustrating a sensor pixel;

FIG. 6 is a plan view schematically illustrating the sensor pixel according to the first embodiment;

FIG. 7 is a sectional view along VII-VII′ of FIG. 6;

FIG. 8 is an explanatory diagram schematically illustrating a lighting pattern of a plurality of light-emitting elements of a light source according to the first embodiment in each detection period;

FIG. 9 is an explanatory diagram for explaining a method for generating a super-resolution image by the detection device according to the first embodiment;

FIG. 10 is a plan view schematically illustrating a stage of the detection device according to the first embodiment;

FIG. 11 is a plan view illustrating a reference marker of the detection device according to the first embodiment;

FIG. 12 illustrates explanatory diagrams for explaining relations of an amount of light transmitted through the reference marker with sensor values of a plurality of photodiodes;

FIG. 13 illustrates explanatory diagrams for explaining the relations of the amount of light transmitted through the reference marker with the sensor values of the photodiodes in a different detection period from that in FIG. 12;

FIG. 14 is a plan view illustrating a modification of the reference marker;

FIG. 15 is a flowchart illustrating an exemplary detection operation of the detection device according to the first embodiment;

FIG. 16 is a sectional view schematically illustrating a detection device according to a second embodiment;

FIG. 17 is a sectional view schematically illustrating the detection device in a different detection period from that in FIG. 16; and

FIG. 18 is a sectional view schematically illustrating a liquid crystal panel according to the second embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

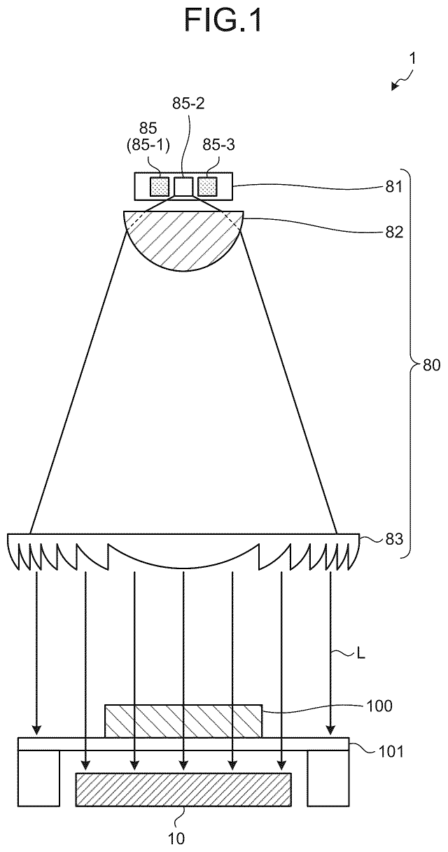

FIG. 1 is a sectional view schematically illustrating a detection device according to a first embodiment. As illustrated in FIG. 1, a detection device 1 includes an optical sensor 10, a stage 101, and a parallel light generator 80. The stage 101 and the parallel light generator 80 are arranged in this order above the optical sensor 10. An object to be detected 100 serving as a detection target is placed on the stage 101 and located between the optical sensor 10 and the parallel light generator 80.

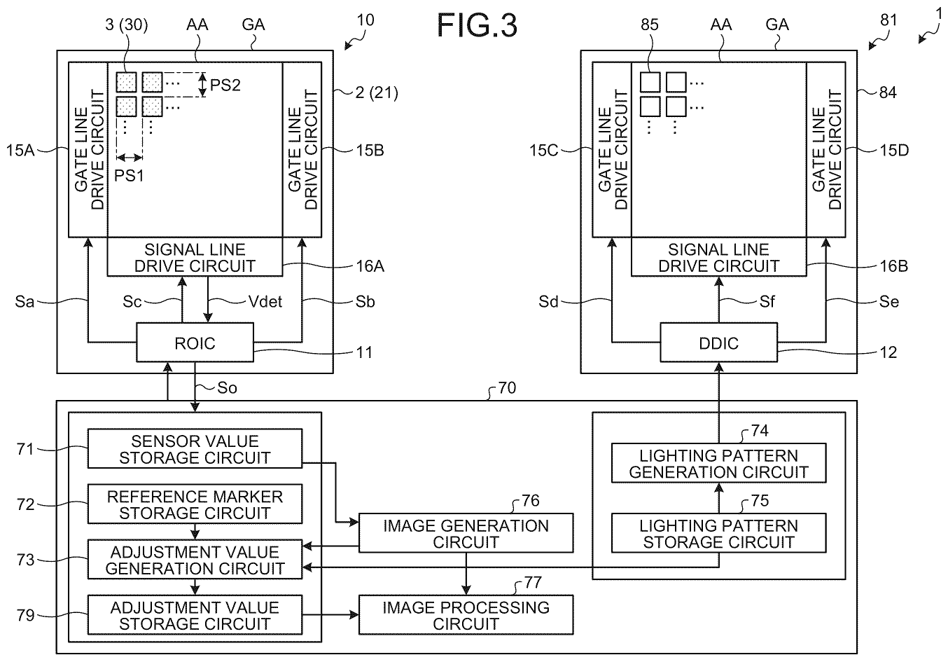

The parallel light generator 80 includes a light source 81, a light distribution lens 82, and a collimating lens 83. The light source 81 is located so as to face a plurality of photodiodes 30 (refer to FIG. 3) of the optical sensor 10 and includes a plurality of light-emitting elements 85 (light emitters). Each of the light-emitting elements 85 is configured as a light-emitting diode (LED), however, the light source 81 may have any configuration.

The collimating lens 83 is located between the photodiodes 30 (refer to FIG. 3) of the optical sensor 10 and the light source 81 and emits parallel light L toward the photodiodes 30. For example, a Fresnel lens is used as the collimating lens 83. The collimating lens 83 is, however, not limited thereto and has any configuration capable of emitting the parallel light L. For example, a lens different from the Fresnel lens, such as an aspherical lens, may be used. The collimating lens 83 is not limited to a single lens and may be a combination of a plurality of lenses.

The light distribution lens 82 is provided between the light source 81 and the collimating lens 83. The light distribution lens 82 is an optical element that appropriately adjusts the light from the light-emitting elements 85 and transmits the adjusted light toward the collimating lens 83. The light distribution lens 82 adjusts, for example, the directivity (spread angle) and/or the light quantity distribution of the light incident from the light-emitting elements 85. The number of the light distribution lenses 82 is not limited to one. A plurality of the light distribution lenses 82 may be provided correspondingly to the light-emitting elements 85. Alternatively, the light distribution lens 82 may be absent.

The object to be detected 100 is, for example, microscopic objects such as cells. The detection device 1 can be applied to detection of the microscopic objects such as the cells. The object to be detected 100 is, however, not limited thereto, and may be a living body such as a finger, a thumb, a palm, or a wrist. For example, the optical sensor 10 may be configured as a fingerprint detection device to detect a fingerprint or a vein detection device to detect a vascular pattern of, for example, veins.

The stage 101 is provided between the photodiodes 30 (refer to FIG. 3) of the optical sensor 10 and the collimating lens 83 of the parallel light generator 80 in a direction orthogonal to a substrate 21 (refer to FIG. 3) of the optical sensor 10. The object to be detected 100 is placed on the stage 101. The upper surface of the stage 101 is formed of a light-transmitting plate-shaped member such as glass, so that the parallel light L from the collimating lens 83 passes through the stage 101 and reaches the optical sensor 10.

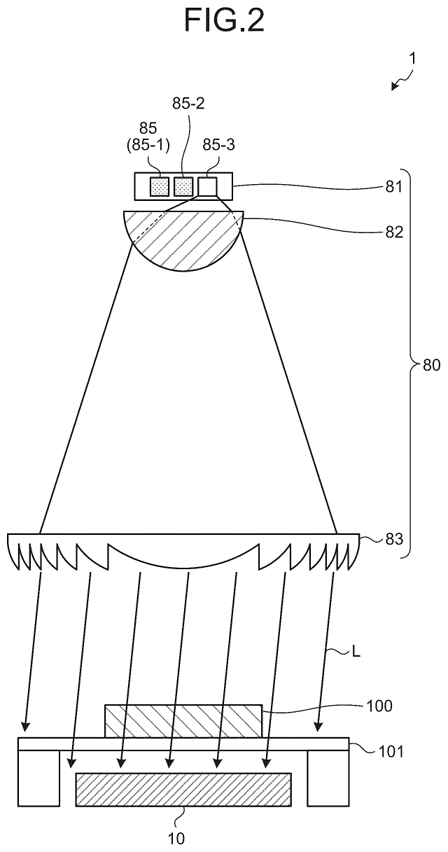

FIG. 2 is a sectional view schematically illustrating the detection device in a detection period different from that of FIG. 1. As illustrated in FIGS. 1 and 2, in the light source 81, at least one of the light-emitting elements 85 is brought into a lit state and the others of the light-emitting elements 85 are brought into an unlit state. The light-emitting elements 85 of the light source 81 are sequentially brought into the lit state in the detection periods.

For example, in the example illustrated in FIG. 1, in the light source 81, a light-emitting element 85-2 located in the center is brought into the lit state, and light-emitting elements 85-1 and 85-3 located on the left and the right are brought into the unlit state. Light emitted from light-emitting element 85-2 is transmitted through the light distribution lens 82 and the collimating lens 83 and travels as the parallel light L toward the photodiodes 30 of the optical sensor 10. In FIG. 1, the parallel light L travels in a direction substantially orthogonal to the optical sensor 10. Part of the parallel light L passes through the object to be detected 100 and enters the photodiodes 30 of the optical sensor 10.

In the example illustrated in FIG. 2, in the light source 81, the light-emitting element 85-3 located on the right side is brought into the lit state, and the light-emitting elements 85-1 and 85-2 are brought into the unlit state. Light emitted from light-emitting element 85-3 is transmitted through the light distribution lens 82 and the collimating lens 83 and travels as the parallel light L toward the photodiodes 30 of the optical sensor 10. In FIG. 2, the parallel light L travels in a direction inclined with respect to the optical sensor 10. Part of the parallel light L passes through the object to be detected 100 and enters the photodiodes 30 of the optical sensor 10.

As illustrated in FIGS. 1 and 2, the collimating lens 83 transmits light at different emission angles depending on the position of the light-emitting element 85 in the lit state. Since the traveling direction of the parallel light L illustrated in FIG. 2 is different from the traveling direction of the parallel light L illustrated in FIG. 1, the parallel light L transmitted through the object to be detected 100 and projected onto the optical sensor 10 is misaligned therebetween. This misalignment causes a positional shift between an image of the object to be detected 100 captured by the optical sensor 10 in FIG. 1 and an image of the object to be detected 100 captured by the optical sensor 10 in FIG. 2.

In the following description, the “positional shift” of images refers to the positional shift of the object to be detected 100 in multiple captured images caused by the misalignment of the projection position of the parallel light L depending on the position of the light-emitting element 85 in the lit state even when the relative positional relation between the optical sensor 10 and the object to be detected 100 remains unchanged in plan view.

In the detection device 1 of the present embodiment, the light source 81 sequentially scans the light-emitting element 85 in the lit state in each detection period to acquire the multiple images having the positional shift. The detection device 1 then combines these multiple images and performs super-resolution processing to generate a super-resolution image that has a higher resolution than that of the photodiodes 30 of the optical sensor 10. Details of a method for acquiring the multiple images and generation of the super-resolution image will be described later.

FIG. 3 is a block diagram illustrating a configuration example of the detection device according to the first embodiment. As illustrated in FIG. 3, the detection device 1 further includes a host integrated circuit (IC) 70 that controls the optical sensor 10 and the light source 81. The optical sensor 10 includes an array substrate 2, a plurality of sensor pixels 3 (photodiodes 30) formed on the array substrate 2, gate line drive circuits 15A and 15B, a signal line drive circuit 16A, and a detection control circuit (ROIC) 11.

The array substrate 2 is formed using the substrate 21 as a base. Each of the sensor pixels 3 is configured with a corresponding one of the photodiodes 30, a plurality of transistors, and various types of wiring. The array substrate 2 with the photodiodes 30 formed thereon is a drive circuit board for driving the sensor for each predetermined detection area and is also called a backplane or an active matrix substrate.

The substrate 21 has a detection area AA and a peripheral area GA. The detection area AA is an area provided with the sensor pixels 3 (photodiodes 30). The peripheral area GA is an area between the outer perimeter of the detection area AA and the outer edges of the substrate 21 and is an area not provided with the sensor pixels 3. The gate line drive circuits 15A and 15B, the signal line drive circuit 16A, and the detection control circuit 11 are provided in the peripheral area GA.

Each of the sensor pixels 3 is an optical sensor including the photodiode 30 as a sensor element. Each of the photodiodes 30 outputs an electric signal corresponding to light emitted thereto. More specifically, the photodiode 30 is a positive-intrinsic-negative (PIN) photodiode or an organic photodiode (OPD) using an organic semiconductor. The sensor pixels 3 (photodiodes 30) are arranged in a matrix having a row-column configuration in the detection area AA.

The detection control circuit 11 is a circuit that supplies control signals Sa, Sb, and Sc to the gate line drive circuits 15A and 15B, and the signal line drive circuit 16A, respectively, to control operations of these circuits. Specifically, the gate line drive circuits 15A and 15B output gate drive signals to sensor gate lines GLS (refer to FIG. 5) based on the control signals Sa and Sb. The signal line drive circuit 16A electrically couples a sensor signal line SLS selected based on the control signal Sc to the detection control circuit 11. The detection control circuit 11 includes a signal processing circuit that processes a detection signal Vdet from each of the photodiodes 30.

The photodiodes 30 included in the sensor pixels 3 perform detection in response to the gate drive signals supplied from the gate line drive circuits 15A and 15B. Each of the photodiodes 30 outputs the electric signal corresponding to the light emitted thereto as the detection signal Vdet to the signal line drive circuit 16A. The detection control circuit 11 processes each of the detection signals Vdet from the photodiodes 30 and outputs a sensor value So based on the detection signal Vdet to the host IC 70. In this way, the detection device 1 detects information on the object to be detected 100.

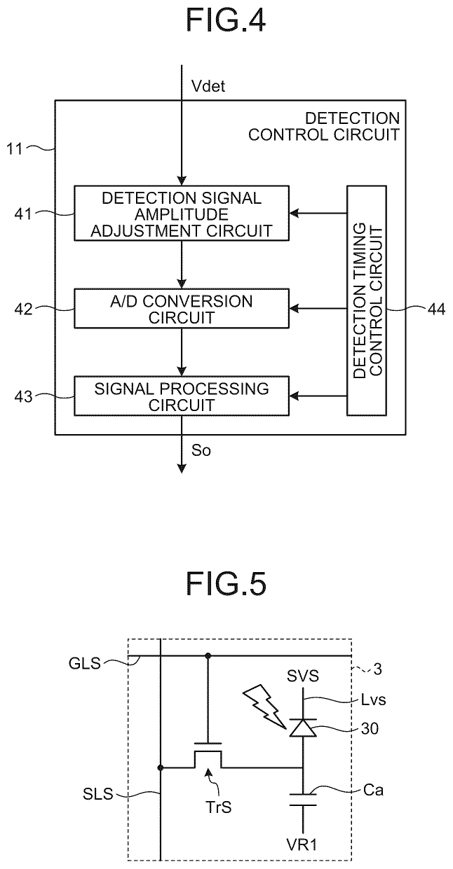

FIG. 4 is a block diagram illustrating a configuration example of the detection control circuit according to the first embodiment. As illustrated in FIG. 4, the detection control circuit 11 includes a detection signal amplitude adjustment circuit 41, an analog-to-digital (A/D) conversion circuit 42, a signal processing circuit 43, and a detection timing control circuit 44. The detection timing control circuit 44 controls the detection signal amplitude adjustment circuit 41, the A/D conversion circuit 42, and the signal processing circuit 43 so as to operate synchronously based on a control signal supplied from the host IC 70 (refer to FIG. 3).

The detection signal amplitude adjustment circuit 41 is a circuit that adjusts the amplitude of the detection signal Vdet output from the photodiode 30 and is configured with an amplifier, for example. The A/D conversion circuit 42 converts analog signals output from the detection signal amplitude adjustment circuit 41 into digital signals. The signal processing circuit 43 is a circuit that processes the digital signals from the A/D conversion circuit 42 and transmits the sensor values So to the host IC 70.

Referring back to FIG. 3, the light source 81 includes an array substrate 84, a plurality of light-emitting elements 85 formed on the array substrate 84, gate line drive circuits 15C and 15D, a signal line drive circuit 16B, and a light-emitting element control circuit (DDIC) 12.

The light-emitting elements 85 are arranged in a matrix having a row-column configuration in an area of the array substrate 84 overlapping the detection area AA. The array substrate 84 is a drive circuit board that drives each of the light-emitting elements 85 to be switched between on (lit state) and off (unlit state).

The light-emitting element control circuit 12 is a circuit that supplies control signals Sd, Se, and Sf to the gate line drive circuits 15C and 15D and the signal line drive circuit 16B, respectively, to control operations of these circuits. Specifically, the gate line drive circuits 15C and 15D output drive signals to gate lines (not illustrated) based on the control signals Sd and Se to select the light-emitting elements 85 in given rows. The signal line drive circuit 16B supplies a light-emitting element control signal to a signal line (not illustrated) selected based on the control signal Sf. As a result, the light source 81 can switch each of the light-emitting elements 85 between the lit state and the unlit state.

The array substrate 84 of the light source 81 is what is called an active matrix substrate, but is not limited thereto. Any method may be used to control on and off the light-emitting elements 85. For example, the light-emitting element control circuit 12 may individually control each of the light-emitting elements 85.

The host IC 70 includes a sensor value storage circuit 71, a reference marker storage circuit 72, an adjustment value generation circuit 73, and an adjustment value storage circuit 79 as control circuits for the optical sensor 10. The sensor value storage circuit 71 is a circuit that stores therein the sensor value So output from the detection control circuit 11 of the optical sensor 10. The reference marker storage circuit 72 is a circuit that stores therein in advance a correlation equation expressing a relation between the position of the light-emitting element 85 in the lit state and the sensor value So of the photodiode 30 at a position overlapping a reference marker 90 (refer to FIG. 10).

The adjustment value generation circuit 73 is a circuit that calculates adjustment values for the positional shifts of the multiple images caused by the on/off switching of the light-emitting elements 85. The adjustment value generation circuit 73 may calculate the adjustment values for the positional shifts of the multiple images based on the correlation equation in the reference marker storage circuit 72, or may calculate the adjustment values based on information on the position of each of the light-emitting elements 85 of the detection device 1 and the design of the optical system. The adjustment value storage circuit 79 is a circuit that stores therein the adjustment values for the positional shifts of the multiple images for respective positions of the light-emitting elements 85 in the lit state. The reference marker storage circuit 72, the adjustment value generation circuit 73, and the adjustment value storage circuit 79 will be described later with reference to FIG. 10 and subsequent figures.

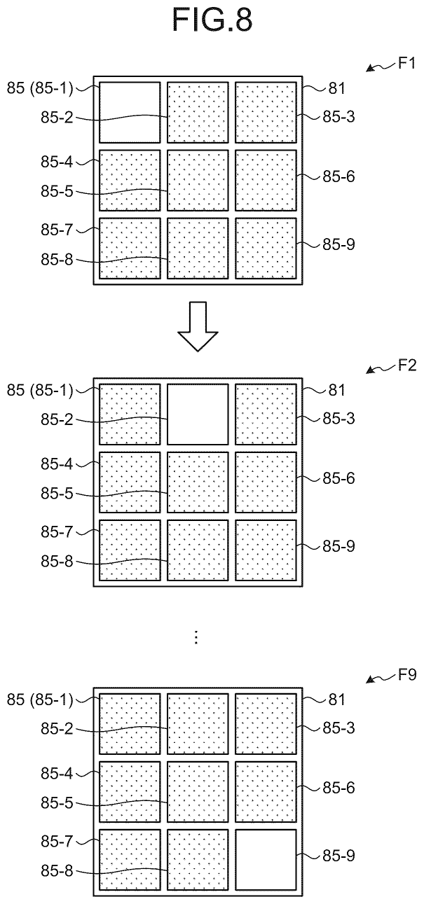

The host IC 70 includes a lighting pattern generation circuit 74 and a lighting pattern storage circuit 75 as control circuits for the light source 81. The lighting pattern storage circuit 75 is a circuit that stores therein information on an arrangement pattern of on (lit state) and off (unlit state) of the light-emitting elements 85 for each detection period F (refer to FIG. 8). The lighting pattern generation circuit 74 is a circuit that generates various control signals based on the information on the arrangement pattern in the lighting pattern storage circuit 75. The lighting pattern generation circuit 74 outputs the light-emitting element control signal including the information on the arrangement pattern of “on and off” of the light-emitting elements 85 to the light-emitting element control circuit 12 in each detection period F.

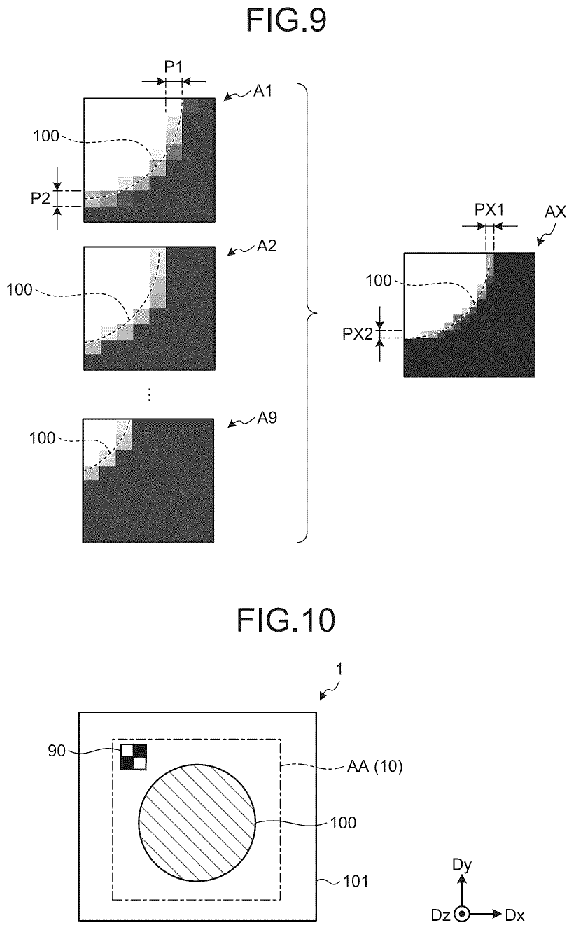

The host IC 70 further includes an image generation circuit 76 and an image processing circuit 77. The image generation circuit 76 is a circuit that generates the multiple images based on the sensor values So from the sensor value storage circuit 71 for the respective detection periods F (that is, for the respective positions of the light-emitting elements 85 in the lit state). The image processing circuit 77 is a circuit that combines the multiple images acquired in the respective detection periods F and performs the super-resolution processing to generate one super-resolution image that has a higher resolution than that of the optical sensors 10. Detailed exemplary operations of the image generation circuit 76 and the image processing circuit 77 will be described later with reference to FIGS. 8 and 9.

Although not illustrated, the host IC 70 includes a control circuit that synchronously controls the detection control circuit 11 and the light-emitting element control circuit 12. That is, the switching of the arrangement pattern of on and off of the light-emitting elements 85 of the light source 81 and the detection of the photodiodes 30 of the optical sensor 10 are synchronously controlled based on a control signal from the host IC 70. The optical sensor 10 includes the two gate line drive circuits 15A and 15B but may include one gate line drive circuit. The light source 81 includes the two gate line drive circuits 15C and 15D but may include one gate line drive circuit.

The following describes a configuration example of the optical sensor 10. FIG. 5 is a circuit diagram illustrating the sensor pixel. As illustrated in FIG. 5, the sensor pixel 3 includes the photodiode 30, a capacitive element Ca, and a first transistor TrS. The first transistor TrS is provided correspondingly to the photodiode 30. The first transistor TrS is configured as a thin-film transistor, and in this example, configured as an n-channel metal oxide semiconductor (MOS) thin-film transistor (TFT). The gate of the first transistor TrS is coupled to the sensor gate line GLS. The source of the first transistor TrS is coupled to the sensor signal line SLS. The drain of the first transistor TrS is coupled to the anode of the photodiode 30 and the capacitive element Ca.

The cathode of the photodiode 30 is supplied with a power supply potential SVS from the detection control circuit 11. The capacitive element Ca is supplied with a reference potential VR1 serving as an initial potential of the capacitive element Ca from the detection control circuit 11.

When the sensor pixel 3 is irradiated with light, a current corresponding to the amount of the light flows through the photodiode 30. As a result, an electric charge is stored in the capacitive element Ca. Turning on the first transistor TrS causes a current corresponding to the electric charge stored in the capacitive element Ca to flow through the sensor signal line SLS. The sensor signal line SLS is coupled to the detection control circuit 11 via the signal line drive circuit 16A. Thus, the optical sensor 10 of the detection device 1 can detect a signal corresponding to the amount of the light received by the photodiode 30 for each of the sensor pixels 3.

The first transistor TrS is not limited to the n-type TFT, and may be configured as a p-type TFT. The pixel circuit of the sensor pixel 3 illustrated in FIG. 5 is merely exemplary. The sensor pixel 3 may be provided with a plurality of transistors corresponding to one photodiode 30.

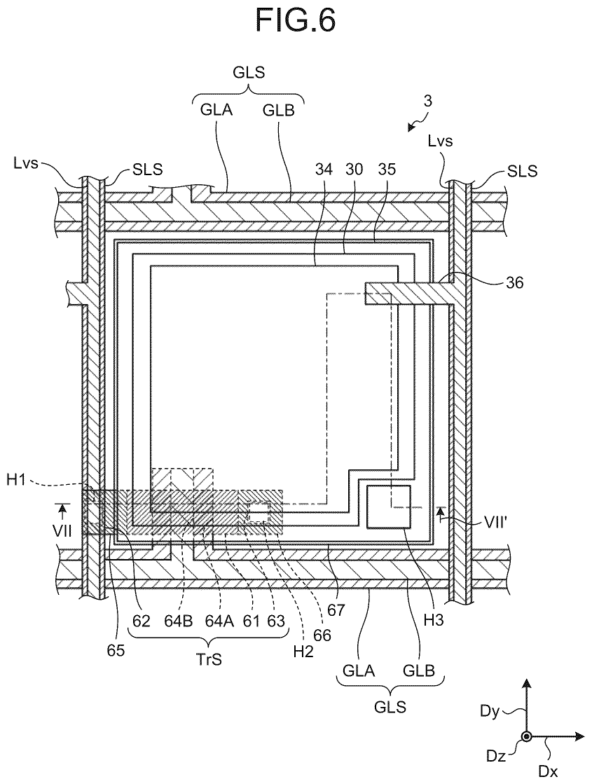

The following describes a detailed configuration of the optical sensor 10. FIG. 6 is a plan view schematically illustrating the sensor pixel according to the first embodiment.

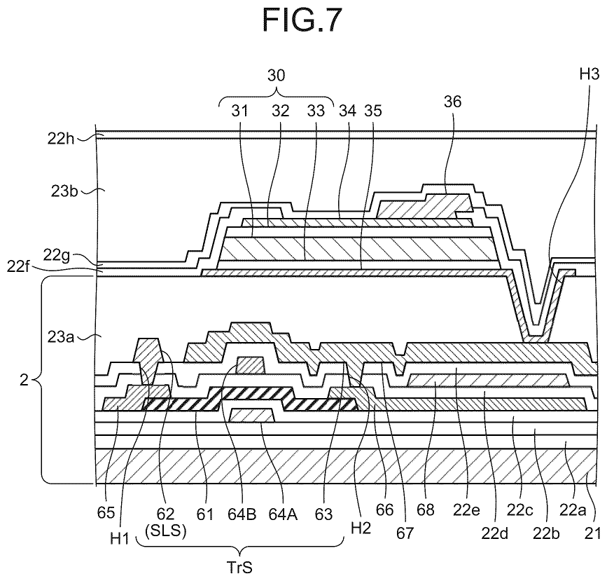

In the following description, a first direction Dx is one direction in a plane parallel to the substrate 21 (refer to FIG. 7). A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed in a direction orthogonal to the substrate 21.

As illustrated in FIG. 6, the sensor pixel 3 is an area surrounded by the sensor gate lines GLS and the sensor signal lines SLS. In the present embodiment, the sensor gate line GLS includes a first sensor gate line GLA and a second sensor gate line GLB. The first sensor gate line GLA is provided so as to overlap the second sensor gate line GLB. The first and the second sensor gate lines GLA and GLB are provided in different layers with insulating layers 22c and 22d (refer to FIG. 7) interposed therebetween. The first and the second sensor gate lines GLA and GLB are electrically coupled together at any point, and are supplied with the gate drive signals having the same potential. At least one of the first sensor gate line GLA and the second sensor gate line GLB is coupled to the gate line drive circuits 15A and 15B. In FIG. 6, the first and the second sensor gate lines GLA and GLB have different widths but may have the same width.

The photodiode 30 is provided in the area surrounded by the sensor gate lines GLS and the sensor signal lines SLS. An upper electrode 34 and a lower electrode 35 are provided for each of the photodiodes 30. The photodiode 30 is a PIN photodiode, for example. The lower electrode 35 is, for example, an anode electrode of the photodiode 30. The upper electrode 34 is, for example, a cathode electrode of the photodiode 30.

The upper electrode 34 is coupled to a power supply signal line Lvs through coupling wiring 36. The power supply signal line Lvs is wiring that supplies the power supply potential SVS to the photodiode 30. In the present embodiment, the power supply signal line Lvs extends in the second direction Dy while overlapping the sensor signal line SLS. The sensor pixels 3 arranged in the second direction Dy are coupled to the power supply signal line Lvs that is shared by those sensor pixels 3. Such a configuration can enlarge an opening for the sensor pixel 3. The lower electrode 35, the photodiode 30, and the upper electrode 34 are substantially quadrilateral in plan view. However, the shapes of the lower electrode 35, the photodiode 30, and the upper electrode 34 are not limited thereto, and can be modified as appropriate.

The first transistor TrS is provided near an intersection between the sensor gate line GLS and the sensor signal line SLS. The first transistor TrS includes a semiconductor layer 61, a source electrode 62, a drain electrode 63, a first gate electrode 64A, and a second gate electrode 64B.

The semiconductor layer 61 is an oxide semiconductor. The semiconductor layer 61 is more preferably a transparent amorphous oxide semiconductor (TAOS) among types of the oxide semiconductor. Using an oxide semiconductor as the first transistor TrS can reduce a leakage current of the first transistor TrS. That is, the first transistor TrS can reduce the leakage current from the sensor pixel 3 that is not selected. Therefore, the optical sensor 10 can improve the signal-to-noise ratio (S/N). The semiconductor layer 61 is, however, not limited thereto, and may be formed of, for example, a microcrystalline oxide semiconductor, an amorphous oxide semiconductor, polysilicon, or low-temperature polycrystalline silicon (LTPS).

The semiconductor layer 61 is provided along the first direction Dx and intersects the first and the second gate electrodes 64A and 64B in plan view. The first and the second gate electrodes 64A and 64B are provided so as to branch from the first and the second sensor gate lines GLA and GLB, respectively. In other words, portions of the first and the second sensor gate lines GLA and GLB that overlap the semiconductor layer 61 serve as the first and the second gate electrodes 64A and 64B. Aluminum (Al), copper (Cu), silver (Ag), molybdenum (Mo), or an alloy of these metals is used as the first and the second gate electrodes 64A and 64B. Channel regions are formed at portions of the semiconductor layer 61 that overlap the first and the second gate electrodes 64A and 64B.

One end of the semiconductor layer 61 is coupled to the source electrode 62 through a contact hole H1. The other end of the semiconductor layer 61 is coupled to the drain electrode 63 through a contact hole H2. A portion of the sensor signal line SLS that overlaps the semiconductor layer 61 serves as the source electrode 62. A portion of a third conductive layer 67 that overlaps the semiconductor layer 61 serves as the drain electrode 63. The third conductive layer 67 is coupled to the lower electrode 35 through a contact hole H3. Such a configuration allows the first transistor TrS to switch between coupling and decoupling between the photodiode 30 and the sensor signal line SLS.

The following describes a layer configuration of the optical sensor 10. FIG. 7 is a sectional view along VII-VII′ of FIG. 6.

In the description of the detection device 1 that includes the optical sensor 10, a direction from the substrate 21 toward the photodiode 30 in a direction (third direction Dz) orthogonal to a surface of the substrate 21 is referred to as “upper side” or “above”. A direction from the photodiode 30 toward the substrate 21 is referred to as “lower side” or “below”.

As illustrated in FIG. 7, the substrate 21 is an insulating substrate and is made using, for example, a glass substrate of quartz, alkali-free glass, or the like. The first transistors TrS, various types of wiring (sensor gate lines GLS and sensor signal lines SLS), and insulating layers are provided on one surface side of the substrate 21 to form the array substrate 2. The photodiodes 30 are arranged on the array substrate 2, that is, on the one surface side of the substrate 21. The substrate 21 may be a resin substrate or a resin film made of a resin such as polyimide.

Insulating layers 22a and 22b are provided on the substrate 21. Insulating layers 22a, 22b, 22c, 22d, 22e, 22f, and 22g are inorganic insulating films, and are formed of silicon oxide (SiO₂) or silicon nitride (SiN). Each of the inorganic insulating layers is not limited to a single layer and may be a multilayered film.

The first gate electrode 64A is provided above the insulating layer 22b. The insulating layer 22c is provided on the insulating layer 22b so as to cover the first gate electrode 64A. The semiconductor layer 61, a first conductive layer 65, and a second conductive layer 66 are provided on the insulating layer 22c. The first conductive layer 65 is provided so as to cover an end of the semiconductor layer 61 coupled to the source electrode 62. The second conductive layer 66 is provided so as to cover an end of the semiconductor layer 61 coupled to the drain electrode 63.

The insulating layer 22d is provided on the insulating layer 22c so as to cover the semiconductor layer 61, the first conductive layer 65, and the second conductive layer 66. The second gate electrode 64B is provided on the insulating layer 22d. The semiconductor layer 61 is provided between the first gate electrode 64A and the second gate electrode 64B in the direction orthogonal to the substrate 21. That is, the first transistor TrS has what is called a dual-gate structure. The first transistor TrS may, however, have a bottom-gate structure that is provided with the first gate electrode 64A and not provided with the second gate electrode 64B, or a top-gate structure that is not provided with the first gate electrode 64A and provided with only the second gate electrode 64B.

The insulating layer 22e is provided on the insulating layer 22d so as to cover the second gate electrode 64B. The source electrode 62 (sensor signal line SLS) and the drain electrode 63 (third conductive layer 67) are provided on the insulating layer 22e. In the present embodiment, the drain electrode 63 is the third conductive layer 67 provided above the semiconductor layer 61 with the insulating layers 22d and 22e interposed therebetween. The source electrode 62 is electrically coupled to the semiconductor layer 61 through the contact hole H1 and the first conductive layer 65. The drain electrode 63 is electrically coupled to the semiconductor layer 61 through the contact hole H2 and the second conductive layer 66.

The third conductive layer 67 is provided in an area overlapping the photodiode 30 in plan view. The third conductive layer 67 is provided also on the upper side of the semiconductor layer 61 and the first and the second gate electrodes 64A and 64B. That is, the third conductive layer 67 is provided between the second gate electrode 64B and the lower electrode 35 in the direction orthogonal to the substrate 21. With this configuration, the third conductive layer 67 has a function as a protective layer that protects the first transistor TrS.

The second conductive layer 66 extends so as to face the third conductive layer 67 in an area not overlapping the semiconductor layer 61. A fourth conductive layer 68 is provided on the insulating layer 22d in the area not overlapping the semiconductor layer 61. The fourth conductive layer 68 is provided between the second conductive layer 66 and the third conductive layer 67. This configuration generates capacitance between the second conductive layer 66 and the fourth conductive layer 68, and capacitance between the third conductive layer 67 and the fourth conductive layer 68. The capacitance generated by the second conductive layer 66, the third conductive layer 67, and the fourth conductive layer 68 serves as capacitance of the capacitive element Ca illustrated in FIG. 5.

A first organic insulating layer 23a is provided on the insulating layer 22e so as to cover the source electrode 62 (sensor signal line SLS) and the drain electrode 63 (third conductive layer 67). The first organic insulating layer 23a is a planarizing layer that planarizes asperities formed by the first transistor TrS and various conductive layers.

The following describes a sectional configuration of the photodiode 30. In the photodiode 30, the lower electrode 35, the photodiode 30, and the upper electrode 34 are stacked in this order on the first organic insulating layer 23a of the array substrate 2.

The lower electrode 35 is provided on the first organic insulating layer 23a and is electrically coupled to the third conductive layer 67 through the contact hole H3. The lower electrode 35 is the anode of the photodiode 30 and is an electrode for reading the detection signal Vdet. For example, a metal material such as molybdenum (Mo) or aluminum (Al) is used as the lower electrode 35. The lower electrode 35 may alternatively be a multilayered film formed of a plurality of layers of these metal materials. The lower electrode 35 may be formed of a light-transmitting conductive material such as indium tin oxide (ITO) or indium zinc oxide (IZO).

The photodiode 30 includes an i-type semiconductor layer 31, an n-type semiconductor layer 32, and a p-type semiconductor layer 33 as semiconductor layers. The i-type semiconductor layer 31, the n-type semiconductor layer 32, and the p-type semiconductor layer 33 are formed of amorphous silicon (a-Si), for example. In FIG. 7, the p-type semiconductor layer 33, the i-type semiconductor layer 31, and the n-type semiconductor layer 32 are stacked in this order in the direction orthogonal to the surface of the substrate 21. However, the photodiode 30 may have a reversed configuration. That is, the n-type semiconductor layer 32, the i-type semiconductor layer 31, and the p-type semiconductor layer 33 may be stacked in this order. Each of the semiconductor layers may be a photoelectric conversion element formed of an organic semiconductor.

The a-Si of the n-type semiconductor layer 32 is doped with impurities to form an n+ region. The a-Si of the p-type semiconductor layer 33 is doped with impurities to form a p+ region. The i-type semiconductor layer 31 is, for example, a non-doped intrinsic semiconductor, and has lower conductivity than that of the n-type semiconductor layer 32 and the p-type semiconductor layer 33.

The upper electrode 34 is the cathode of the photodiode 30 and is an electrode for supplying the power supply potential SVS to the photoelectric conversion layers. The upper electrode 34 is, for example, a light-transmitting conductive layer of, for example, ITO, and a plurality of the upper electrodes 34 are provided for the respective photodiodes 30.

The insulating layers 22f and 22g are provided on the first organic insulating layer 23a. The insulating layer 22f covers the periphery of the upper electrode 34, and is provided with an opening in a position overlapping the upper electrode 34. The coupling wiring 36 is coupled to a portion of the upper electrode 34 not provided with the insulating layer 22f. The insulating layer 22g is provided on the insulating layer 22f so as to cover the upper electrode 34 and the coupling wiring 36. A second organic insulating layer 23b serving as a planarizing layer is provided on the insulating layer 22g. In the case of the organic semiconductor photodiode 30, an insulating layer 22h may be further provided thereon.

The following describes an exemplary detection method of the detection device 1 according to the present embodiment. FIG. 8 is an explanatory diagram schematically illustrating a lighting pattern of the light-emitting elements of the light source according to the first embodiment in each detection period. In FIG. 8, among the light-emitting elements 85, the light-emitting elements 85 in the lit state are illustrated in white, and the light-emitting elements 85 in the unlit state are illustrated with shading.

As illustrated in FIG. 8, the light-emitting elements 85 of the light source 81 are arranged in a matrix having a row-column configuration in plan view. In the example illustrated in FIG. 8, a plurality of light-emitting elements 85-1, 85-2, . . . , 85-9 are arranged in three rows and three columns. In the following description, the light-emitting elements 85-1, 85-2, 85-9 will each be simply referred to as the light-emitting element 85 when they need not be distinguished from one another.

As illustrated in FIG. 8, the light source 81 sequentially brings the light-emitting elements 85 into the lit state in each of the detection periods F. In a detection period F1, the light source 81 brings the light-emitting element 85-1 of the light-emitting elements 85 into the lit state, and brings the other light-emitting elements 85-2 to 85-9 into the unlit state. In a next detection period F2, the light source 81 brings the light-emitting element 85-2 of the light-emitting elements 85 into the lit state, and brings the other light-emitting elements 85-1 and 85-3 to 85-9 into the unlit state. Subsequently, in the same way, the light source 81 changes the light-emitting element 85 to be in the lit state for each of the detection periods F. In a last detection period F9, the light-emitting element 85-9 of the light-emitting elements 85 is brought into the lit state, and the other light-emitting elements 85-1 to 85-8 are brought into the unlit state.

However, FIG. 8 is merely exemplary, and the number of the light-emitting elements 85 may be eight or smaller, or 10 or larger. The light-emitting elements 85 is not limited to being arranged in a matrix and may be arranged in another pattern, such as a triangle lattice pattern. In FIG. 8, one of the light-emitting elements 85 is brought into the lit state in each detection period F. However, the light source 81 may switch between the lit state and the unlit state on a light-emitting element group basis depending on the size and the amount of light of the light-emitting element 85. Each light-emitting element group includes the adjacent two or more light-emitting elements 85.

The photodiode 30 of the optical sensor 10 outputs the detection signal Vdet (sensor value So) corresponding to the position of the light-emitting element 85 in the lit state sequentially for each detection period F1, F2, . . . , F9. Specifically, since the light-emitting elements 85 in the lit state are sequentially scanned in the detection periods F, the emission angle of the parallel light L from the collimating lens 83 differs for each detection period F (that is, for the respective positions of the light-emitting elements 85 in the lit state) in the same way as in the examples illustrated in FIGS. 1 and 2.

The relative positional relation between the optical sensor 10 and the object to be detected 100 is constant in the detection periods F, but the emission angle of the parallel light L differs between the detection periods F, so that the position of projection of the parallel light L on the optical sensor 10 also differs therebetween. The photodiodes 30 output the detection signals Vdet (sensor values So) corresponding to the positions of projection of the parallel light L in each detection period F.

FIG. 9 is an explanatory diagram for explaining a method for generating the super-resolution image by the detection device according to the first embodiment. As illustrate in FIG. 9, the image generation circuit 76 (refer to FIG. 3) generates the multiple images A1, A2, . . . , and A9 based on the sensor values So in the sensor value storage circuit 71 for the respective detection periods F. The images A1, A2, . . . , A9 correspond, for example, to images acquired in the detection periods F1, F2, . . . , F9 illustrated in FIG. 8.

Although the relative positional relation between the optical sensor 10 and the object to be detected 100 is constant in the detection periods F for the images A1, A2, . . . , A9, the position of projection of the parallel light L on the optical sensor 10 differs between the detection periods F for the images A1, A2, . . . , A9. Therefore, the positional shift of the captured object to be detected 100 occurs between the images A1, A2, . . . , A9. As described above, the information on the adjustment values for the positional shifts of the images A1, A2, . . . , A9 are calculated in advance based on the positions of the light-emitting elements 85 (positions of the light-emitting elements 85 in the lit state) of the detection device 1 and the design of the optical system, and stored in the adjustment value storage circuit 79 (refer to FIG. 3) as the adjustment values for the positional shifts of the images. The adjustment value for the positional shift of the images is calculated, for example, for each of the positions of the light-emitting elements 85 in the lit state and stored in the adjustment value storage circuit 79 in association with the position of the light-emitting element 85 in the lit state.

Pixel pitches P1 and P2 (resolution) of each of the images A1, A2, . . . , A9 are determined correspondingly to arrangement pitches PS1 and PS2 of the photodiodes 30 (refer to FIG. 3). The pixel pitches P1 and P2 are equal to the arrangement pitches PS1 and PS2 of the photodiodes 30. The arrangement pitch PS1 of the photodiodes 30 in the first direction Dx is defined by the arrangement pitch of the sensor signal lines SLS (refer to FIG. 6) in the first direction Dx. The arrangement pitch PS2 of the photodiodes 30 in the second direction Dy is defined by the arrangement pitch of the sensor gate lines GLS (refer to FIG. 6) in the second direction Dy.

The image processing circuit 77 (refer to FIG. 3) performs the super-resolution processing based on the images A1, A2, . . . , A9 acquired in the respective detection periods F by the image generation circuit 76 and the adjustment values for the positional shifts of the images acquired from the adjustment value storage circuit 79. For example, the image processing circuit 77 superimposes to combine the images A1, A2, . . . , A9 so as to match the positions of the object to be detected 100 of the images with each other based on the adjustment values for the positional shifts of the images, and thus generates a super-resolution image AX. The image processing circuit 77 can employ, for example, the methods described in Yuji Nakazawa, Takashi Komatsu & Takahiro Saito: “Sub-pixel registration for super high resolution image acquisition based on temporal integration”, ICIAP 1995: Image Analysis and Processing, pp 387-392, and Shin Aoki: “Super Resolution Processing by Plural Number of Lower Resolution Images”, Ricoh Technical Report No. 24, November 1998, as specific examples of the super-resolution processing.

The amount of shift of each of the images A1, A2, . . . , A9 in the respective detection periods F (specifically, the magnitude of the positional shift of the object to be detected 100) in plan view is a non-integer multiple of each of the arrangement pitches PS1 and PS2 of the photodiodes 30. In other words, for example, the design of the optical system including the light-emitting elements 85, the collimating lens 83, and the like, and the arrangement pattern of the light-emitting elements 85 in the lit state are determined so that the amount of shift of each of the images A1, A2, . . . , A9 is a non-integer multiple of each of the arrangement pitches PS1 and PS2 of the photodiodes 30.

As a result, as illustrated in FIG. 9, the resolution of the super-resolution image AX is improved as compared with the resolution of the original images A1, A2, . . . , A9; and the outline of the object to be detected 100 in the super-resolution image AX is more clearly reproduced than the outline of the object to be detected 100 in each of the images A1, A2, . . . , A9. In other words, pixel pitches PX1 and PX2 of the super-resolution image AX are smaller than the pixel pitches P1 and P2 of each of the original images A1, A2, . . . , A9.

As described above, the image processing circuit 77 performs the super-resolution processing based on the images A1, A2, . . . , A9, and thereby, the detection device 1 can generate the super-resolution image AX having the resolution exceeding the sensor resolution of the optical sensor 10. The detection device 1 of the present embodiment can capture the images A1, A2, . . . , A9 having a positional shift by switching between on and off of the light-emitting elements 85 of the light source 81 while keeping the relative positional relation between the object to be detected 100 and the optical sensor 10 constant. Therefore, the mechanism of the stage 101 for moving the object to be detected 100 and the configuration for moving the optical sensor 10 are not necessary, and the detection device 1 can capture multiple images A1, A2, . . . , A9 having a positional shift, with a simple configuration.

Although the above has described the example of using the adjustment values for the shifts of the images that have been calculated in advance and stored in the adjustment value storage circuit 79, the present disclosure is not limited to this example. The image processing circuit 77 may use the adjustment values obtained using the reference marker 90.

The following describes a method for adjusting the shift of the images using the reference marker 90. FIG. 10 is a plan view schematically illustrating the stage of the detection device according to the first embodiment. As illustrated in FIG. 10, the reference marker 90 is provided on the stage 101. In other words, the reference marker 90 is located between the photodiodes 30 of the optical sensor 10 and the collimating lens 83 of the parallel light generator 80 (refer to FIG. 1).

The reference marker 90 is provided in an area that overlaps the detection area AA of the stage 101 and does not overlap the object to be detected 100, in plan view. The reference marker 90 is located at, for example, a corner of the area that overlaps the detection area AA of the stage 101.

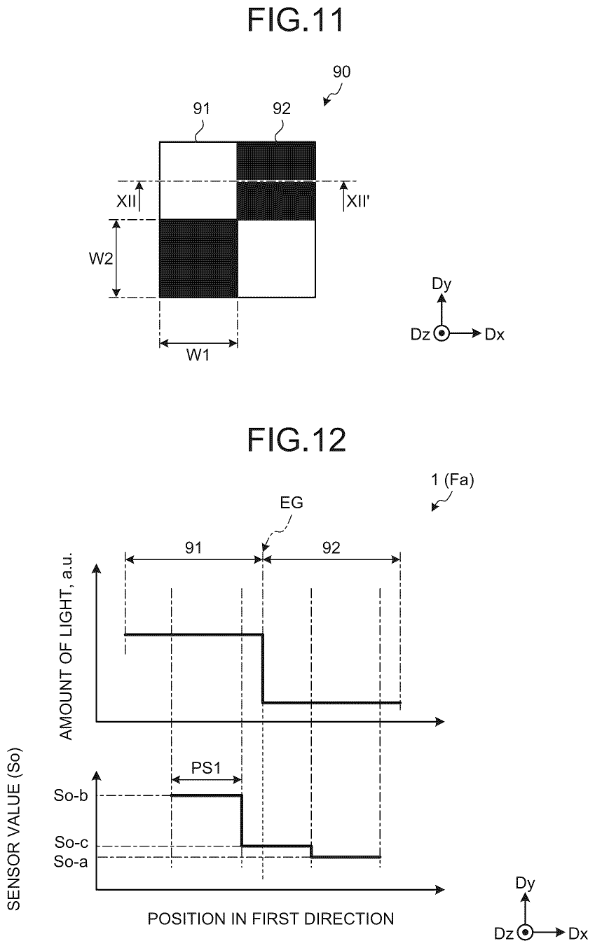

FIG. 11 is a plan view illustrating the reference marker of the detection device according to the first embodiment. As illustrated in FIG. 11, the reference marker 90 has a first region 91 having higher light transmittance and a second region 92 having lower light transmittance than the first region 91. In the example illustrated in FIG. 11, the first region 91 is a light-transmitting region formed of a light-transmitting member, and the second region 92 is a light-blocking region formed of a black member.

The first and the second regions 91 and 92 of the reference marker 90 are arranged in a grid. Specifically, the first and the second regions 91 and 92 are arranged adjacent to each other in the first direction Dx. The first and the second regions 91 and 92 are also arranged adjacent to each other in the second direction Dy.

A width W1 in the first direction Dx of the second region 92 is equal to the width in the first direction Dx of the first region 91. A width W2 in the second direction Dy of the second region 92 is equal to the width in the second direction Dy of the first region 91. The widths W1 and W2 of the second region 92 are larger than twice the arrangement pitches PS1 and PS2 of the photodiodes 30 (refer to FIG. 3). More preferably, the widths W1 and W2 of the second region 92 are non-integer multiples of the arrangement pitches PS1 and PS2 of the photodiodes 30.

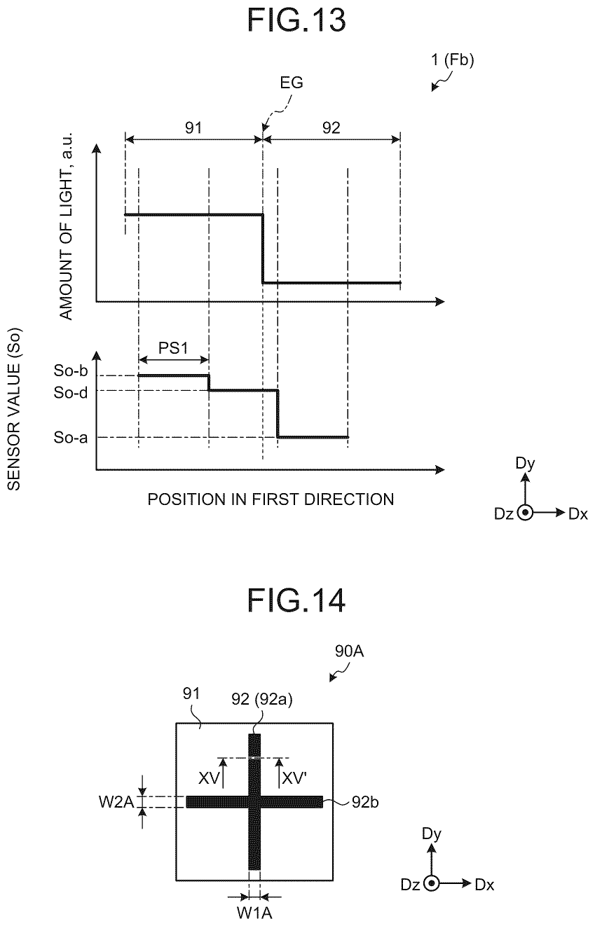

FIG. 12 illustrates explanatory diagrams for explaining relations of the amount of light transmitted through the reference marker with the sensor values of the photodiodes. FIG. 13 illustrates explanatory diagrams for explaining the relations of the amount of light transmitted through the reference marker with the sensor values of the photodiodes in a different detection period from that in FIG. 12.

FIGS. 12 and 13 schematically illustrate detection results when the reference marker 90 is detected along line XII-XII′ illustrated in FIG. 11. Specifically, the upper graphs in FIGS. 12 and 13 each illustrate the relation between the position in the first direction Dx and the amount of light transmitted through the reference marker. The lower graphs in FIGS. 12 and 13 each illustrate the relations between the position in the first direction Dx and the sensor values So of the photodiodes 30. The lower graphs in FIGS. 12 and 13 each illustrate the sensor values So of three of the photodiodes 30 adjacent to one another in the first direction Dx in such a manner that the relation is associated with the arrangement pitch PS1 of the photodiodes 30. The position of the light-emitting element 85 in the lit state differs between a detection period Fa illustrated in FIG. 12 and a detection period Fb illustrated in FIG. 13.

As illustrated in FIG. 12, in the detection period Fa, the photodiode 30 in a position overlapping the first region 91 of the reference marker 90 outputs a sensor value So-b. The photodiode 30 in a position overlapping the second region 92 of the reference marker 90 outputs a sensor value So-a smaller than the sensor value So-b. The photodiode 30 in an area overlapping a boundary EG between the first and the second regions 91 and 92 of the reference marker 90 outputs a sensor value So-c.

In the photodiode 30 in the area overlapping the boundary EG, a partial area corresponding to the first region 91 is irradiated with the parallel light L transmitted through the first region 91. In the photodiode 30 in the area overlapping the boundary EG, the other area corresponding to the second region 92 is not irradiated with the parallel light L because the parallel light L is blocked in the second region 92. Therefore, the sensor value So-c corresponding to the area lying across the boundary EG is larger than the sensor value So-a corresponding to the second region 92 and smaller than the sensor value So-b corresponding to the first region 91.

As illustrated in FIG. 13, during the detection period Fb different from the period in FIG. 12, the sensor value So-b of the photodiode 30 in the position overlapping the first region 91 and the sensor value So-a of the photodiode 30 in the position overlapping the second region 92 of the reference marker 90 are equal to those in FIG. 12.

In the detection period Fb illustrated in FIG. 13, the position of the light-emitting element 85 in the lit state differs from that in the detection period Fa illustrated in FIG. 12. For this reason, even though the relative positional relation between the optical sensor 10 and the reference marker 90 is the same, the shift in position of projection of the parallel light L transmitted through the first region 91 occurs depending on the position of the light-emitting element 85 in the lit state. In the example illustrated in FIG. 13, the area of the portion of the photodiode 30 at the position overlapping the boundary EG that is irradiated with the parallel light L transmitted through the first region 91 is larger than that in FIG. 12. Therefore, the sensor value So-d corresponding to the area overlapping the boundary EG becomes a larger value than the sensor value So-c corresponding to the area overlapping the boundary EG in FIG. 12.

In this way, the sensor value So of the photodiode 30 at the position overlapping the boundary EG is correlated with the amount of positional shift of the captured image at the boundary EG. The detection device 1 sequentially brings the light-emitting elements 85 into the lit state and acquires the sensor value So of the photodiode 30 at the position overlapping the boundary EG for each of the positions of the light-emitting elements 85 in the lit state, in advance. As a result, as described above, the reference marker storage circuit 72 (refer to FIG. 3) stores therein in advance the correlation equation expressing the relation between the sensor value So of the photodiode 30 at the position overlapping the reference marker 90 (refer to FIG. 10) and the position of the light-emitting element 85 in the lit state. The adjustment value generation circuit 73 calculates the adjustment values for the positional shifts of the multiple images for the respective positions of the light-emitting elements 85 in the lit state, based on the correlation equation in the reference marker storage circuit 72.

While the correlation between the sensor value So of the photodiode 30 and the amount of positional shift of the captured image at the boundary EG in the first direction Dx has been described with reference to FIGS. 12 and 13, the reference marker storage circuit 72 (refer to FIG. 3) also acquires the correlation between the sensor value So of the photodiode 30 and the amount of positional shift of the captured image at the boundary EG in the second direction Dy.

FIG. 14 is a plan view illustrating a modification of the reference marker. FIG. 11 illustrates the pattern in which the first region 91 and the second region 92 of the reference marker 90 are arranged in a grid, but the pattern is not limited to this pattern. The reference marker 90 can be in any pattern that has the boundary EG between the first region 91 and the second region 92 in each of the first direction Dx and the second direction Dy.

As illustrated in FIG. 14, a reference marker 90A according to the modification is provided with the first region 91 as a background and the second region 92 having a cross shape. The second region 92 is provided with a portion 92a extending in the second direction Dy and a portion 92b extending in the first direction Dx that intersect each other. In the present modification, two boundaries EG between the first region 91 and the second region 92 are present in an area along line XV-XV′ intersecting the portion 92a of the second region 92. Two boundaries EG between the first region 91 and the second region 92 are also present in an area intersecting the portion 92b of the second region 92.

A width W1A of the portion 92a of the second region 92 and a width W2A of the portion 92b of the second region 92 are larger than twice the arrangement pitches PS1 and PS2 of the photodiodes 30 (refer to FIG. 3). The widths W1A and W2A are more preferably non-integer multiples of the arrangement pitches PS1 and PS2 of the photodiodes 30.

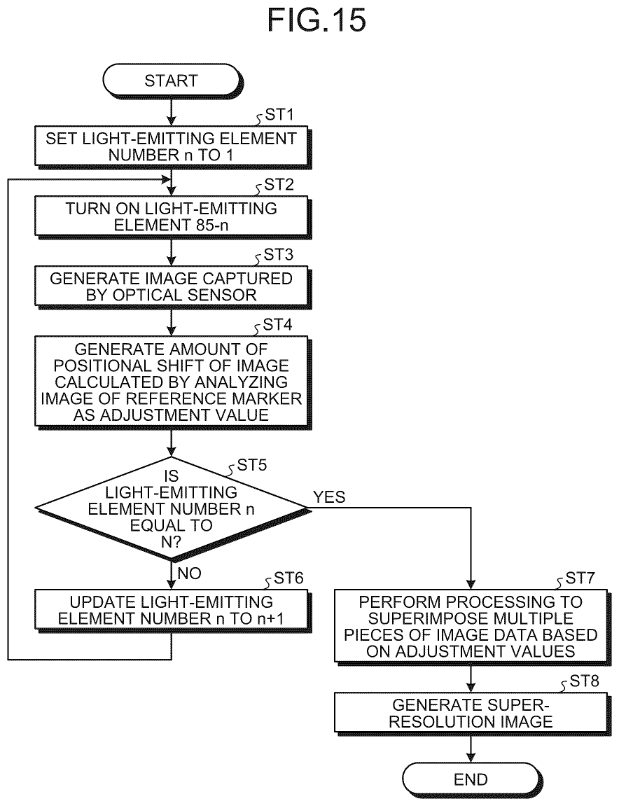

The following describes an exemplary detection operation of the detection device with reference to FIGS. 3, 15, and other figures. FIG. 15 is a flowchart illustrating the exemplary detection operation of the detection device according to the first embodiment. First, the lighting pattern generation circuit 74 of the host IC 70 sets a light-emitting element number n to 1 based on information from the lighting pattern storage circuit 75 (Step ST1). The light-emitting element number n is a natural number in a range from 1 to N. That is, light-emitting elements 85 are provided as light-emitting elements 85-1 to 85-N.

The light source 81 turns on the nth (n=1) light-emitting element 85-n based on the control signal from the lighting pattern generation circuit 74 (Step ST2). The light source 81 brings the light-emitting elements 85 other than the light-emitting element 85-n into the unlit state.

The photodiodes 30 of the optical sensor 10 output the sensor values So based on the parallel light L from the light-emitting element 85-n in the lit state, and the sensor value storage circuit 71 stores therein the sensor values So. The image generation circuit 76 generates an image based on the sensor values So of the optical sensor 10 (Step ST3). The image generation circuit 76 also generates an image of the reference marker 90 along with an image of the object to be detected 100.

The adjustment value generation circuit 73 calculates the amount of positional shift of an image corresponding to the light-emitting element 85-n in the lit state by analyzing the image of the reference marker 90 generated at Step ST3, and generates the calculated amount of positional shift of the image as an adjustment value (Step ST4). The adjustment value storage circuit 79 stores therein the adjustment value corresponding to the light-emitting element 85-n in the lit state.

The lighting pattern generation circuit 74 determines whether the light-emitting element number n satisfies n=N (Step ST5). If the light-emitting element number n does not satisfy n=N (No at Step ST5), the lighting pattern generation circuit 74 updates the light-emitting element number n to n+1 (Step ST6). The detection device 1 then performs the processing at Steps ST2 to ST4 while changing the light-emitting element 85 to be in the lit state.

If the light-emitting element number n satisfies n=N (Yes at Step ST5), that is, if the light source 81 has completed the scanning of the light-emitting elements 85 in the lit state from the light-emitting element 85-1 to the light-emitting element 85-N, the image processing circuit 77 performs processing to superimpose the images acquired from the image generation circuit 76 for the respective positions of the light-emitting elements 85 in the lit state, based on the adjustment values of the adjustment value storage circuit 79 calculated for the respective positions of the light-emitting elements 85 in the lit state (Step ST7).

Thus, the image processing circuit 77 performs the super-resolution processing to generate the super-resolution image AX having the resolution exceeding the sensor resolution of the optical sensor 10 (Step ST8).

The generation of the adjustment value need not be performed at Step ST4 and may be performed in each predetermined period, such as at the start-up of the detection device 1. At Step ST4, the generated adjustment value may be compared with a value given by the correlation equation stored in the reference marker storage circuit 72, and if a difference occurs between these values, a calibration may be performed to update the correlation equation.

### Second Embodiment

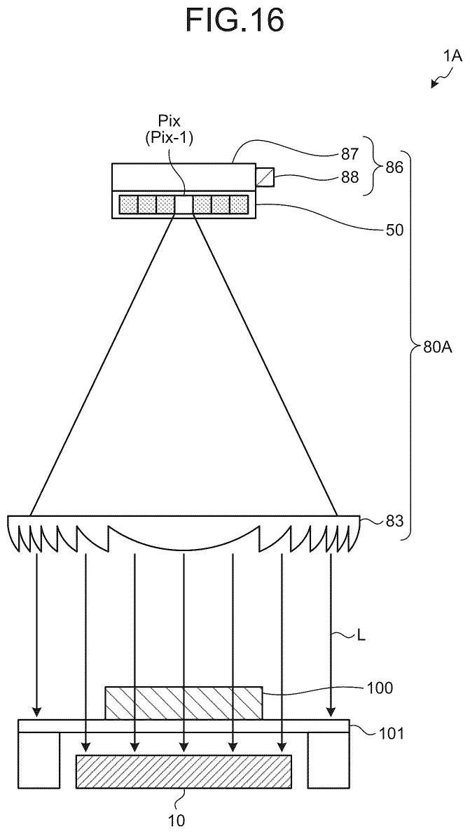

FIG. 16 is a sectional view schematically illustrating a detection device according to a second embodiment. In the following description, the same components as those described in the embodiment described above are denoted by the same reference numerals, and the description thereof will not be repeated.

As illustrated in FIG. 16, a detection device 1A according to the second embodiment includes a liquid crystal panel 50 and a light source 86 instead of the light source 81 and the light distribution lens 82 of the first embodiment described above. That is, a parallel light generator 80A of the second embodiment includes the liquid crystal panel 50, the light source 86, and the collimating lens 83. In the parallel light generator 80A, the collimating lens 83, the liquid crystal panel 50, and the light source 86 are arranged in this order in the direction orthogonal to the substrate 21 of the optical sensor 10.

The light source 86 is a backlight for the liquid crystal panel 50 and is provided on the back surface of the liquid crystal panel 50 (surface opposite the optical sensor 10). The light source 86 includes at least one light-emitting element 88 and emits light toward the liquid crystal panel 50. Specifically, the light source 86 includes a light-transmitting light guide plate 87 and the light-emitting element 88 facing a side surface of the light guide plate 87. The light-emitting element 88 is configured as an LED, and a plurality of the light-emitting elements 88 are arranged along the side surface of the light guide plate 87. The light guide plate 87 is disposed so as to face the liquid crystal panel 50. The light emitted from the light-emitting element 88 propagates while repeatedly reflecting and scattering in the light guide plate 87, and part of the light in the light guide plate 87 is emitted to the liquid crystal panel 50.

The liquid crystal panel 50 is disposed so as to face the photodiodes 30 (refer to FIG. 3) of the optical sensor 10 and includes a plurality of pixels Pix (light emitters). The pixels Pix are arranged in a matrix having a row-column configuration in plan view, although not illustrated. The liquid crystal panel 50 serves as an optical filter layer that switches between a light transmissive state and a non-transmissive state for each of the pixels Pix. The liquid crystal panel 50 transmits light that has been emitted from the light source 86 and passed through the pixel Pix in the transmissive state toward the collimating lens 83. In the liquid crystal panel 50, the pixels Pix in the non-transmissive state block the light from the light source 86 and do not transmit the light toward the collimating lens 83.

The collimating lens 83 is located between the photodiodes 30 (refer to FIG. 3) of the optical sensor 10 and the liquid crystal panel 50 and emits the parallel light L toward the photodiodes 30.

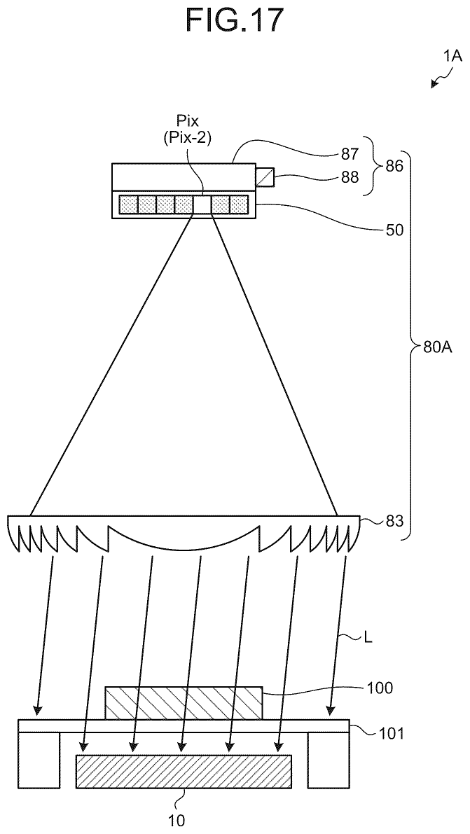

FIG. 17 is a sectional view schematically illustrating the detection device in a different detection period from that in FIG. 16. As illustrated in FIGS. 16 and 17, in the liquid crystal panel 50, at least one of the Pixels Pix is brought into the transmissive state and the other pixels Pix is brought into the non-transmissive state. The liquid crystal panel 50 then sequentially scans the pixels Pix in the transmissive state in each detection period. The photodiodes 30 of the optical sensor 10 sequentially output the detection signals Vdet (sensor values So) corresponding to the light transmitted through the pixels Pix in the transmissive state in the respective detection periods.

For example, in the example illustrated in FIG. 16, in the liquid crystal panel 50, a pixel Pix-1 located in the center is brought into the transmissive state, and the other pixels Pix are brought into the non-transmissive state. The light from the light source 86 passes through the pixel Pix-1 in the transmissive state in the liquid crystal panel 50. Light transmitted from the pixel Pix-1 in the transmissive state in the liquid crystal panel 50 is converted into the parallel light L by the collimating lens 83, and the parallel light L travels toward the photodiodes 30 of the optical sensor 10. In FIG. 16, the parallel light L travels in a direction substantially orthogonal to the optical sensor 10. Part of the parallel light L passes through the object to be detected 100 and enters the photodiodes 30 of the optical sensor 10.

In the example illustrated in FIG. 17, in the liquid crystal panel 50, a pixel Pix-2 adjacent to the pixel Pix-1 is brought into the transmissive state, and the other pixels Pix are brought into the non-transmissive state. The light from the light source 86 passes through the pixel Pix-2 in the transmissive state in the liquid crystal panel 50. Light transmitted from the pixel Pix-2 in the transmissive state in the liquid crystal panel 50 is converted into the parallel light L by the collimating lens 83, and the parallel light L travels toward the photodiodes 30 of the optical sensor 10. In FIG. 17, the parallel light L travels in a direction inclined with respect to the optical sensor 10. Part of the parallel light L passes through the object to be detected 100 and enters the photodiodes 30 of the optical sensor 10.

In the present embodiment, the collimating lens 83 transmits the light at different emission angles depending on the position of the pixel Pix in the transmissive state. As a result, in the same way as in the first embodiment, the traveling direction of the parallel light L illustrated in FIG. 17 is different from the traveling direction of the parallel light L illustrated in FIG. 16. Therefore, the parallel light L transmitted through the object to be detected 100 is projected on a shifted position of the optical sensor 10. Therefore, when the liquid crystal panel 50 sequentially scans the pixel Pix in the transmissive state, a positional shift between multiple images of the object to be detected 100 captured by the optical sensor 10 occurs for each position of the pixel Pix in the transmissive state. In the same way as in the first embodiment described above, the detection device 1A can generate the super-resolution image AX by combining the multiple images having the positional shift.

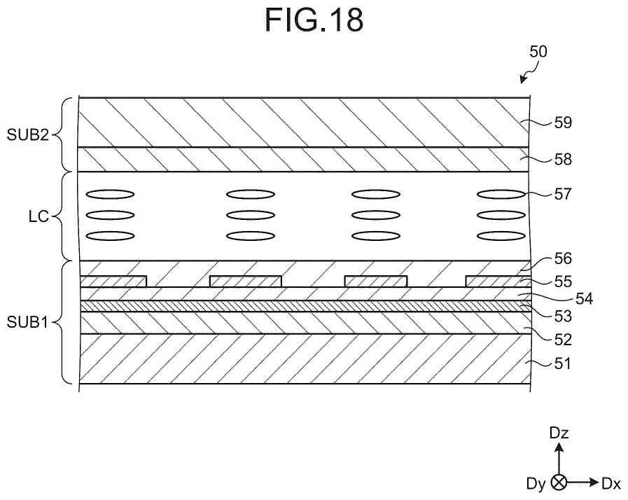

FIG. 18 is a sectional view schematically illustrating the liquid crystal panel according to the second embodiment. As illustrated in FIG. 18, the liquid crystal panel 50 includes, for example, an array substrate SUB1, a counter substrate SUB2, and a liquid crystal layer LC. The counter substrate SUB2 is disposed so as to face the array substrate SUB1. The liquid crystal layer LC is enclosed between the array substrate SUB1 and the counter substrate SUB2.

The array substrate SUB1 includes a first insulating substrate 51, a circuit forming layer 52, a common electrode 53, an insulating film 54, a pixel electrode 55, and a lower orientation film 56. The circuit forming layer 52, the common electrode 53, the insulating film 54, the pixel electrode 55, and the lower orientation film 56 are stacked in this order in the third direction Dz on the first insulating substrate 51.

The first insulating substrate 51 is a light-transmitting glass or film substrate. The circuit forming layer 52 is a layer in which the pixel circuit including transistors of the pixel Pix and various types of wiring is formed. The common electrode 53 is an electrode that is supplied with a predetermined constant potential. The insulating film 54 insulates the common electrode 53 from the pixel electrode 55. The pixel electrode 55 is provided for each of the pixels Pix and is individually controlled in potential. The lower orientation film 56 is provided so as to cover the pixel electrodes 55 and the insulating film 54.

The counter substrate SUB2 includes a second insulating substrate 59 and an upper orientation film 58. The upper orientation film 58 is provided on a surface of the second insulating substrate 59 facing the first insulating substrate 51. The upper orientation film 58 serves as a surface on the liquid crystal layer LC side of the counter substrate SUB2. In the present embodiment, the array substrate SUB1 and the counter substrate SUB2 are provided with no color filter. That is, the liquid crystal panel 50 emits monochrome light toward the photodiode 30.

Although not illustrated in FIG. 18, optical elements including polarizing plates are provided on respective outer surfaces of the first insulating substrate 51 and the second insulating substrate 59. The polarizing axes of a pair of the polarizing plates are in a crossed Nicols positional relation in plan view. The counter substrate SUB2 may be provided with a color filter or a light-blocking film, as required.

The liquid crystal layer LC modulates light passing therethrough according to the state of an electric field, and uses, for example, liquid crystals in a horizontal electric field mode, such as in-plane switching (IPS) including fringe field switching (FFS). In the present embodiment, the liquid crystal layer LC is driven by the horizontal electric field generated between the pixel electrode 55 and the common electrode 53 provided on the array substrate, and the orientation of liquid crystal molecules 57 included in the liquid crystal layer LC is controlled.

However, the liquid crystal panel 50 is not limited to this configuration, and may be a vertical electric field panel. In that case, the pixel electrode is provided on the array substrate SUB1 and the common electrode is provided on the counter substrate SUB2. Examples of the vertical electric field liquid crystal panel include, but are not limited to, a twisted nematic (TN) panel, a vertical alignment (VA) panel, and an electrically controlled birefringence (ECB) panel in which what is called a vertical electric field is applied to the liquid crystal layer.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omission, substitution, and change of the components can be made without departing from the gist of the embodiments and the modification described above.

What is claimed is:

1. A detection device comprising:
a plurality of photodiodes provided on a substrate;
a plurality of light emitters arranged so as to face the photodiodes; and
a collimating lens that is located between the photodiodes and the light emitters and is configured to emit parallel light toward the photodiodes, wherein
at least one of the light emitters is configured to be brought into a lit state and other of the light emitters are configured to be brought into an unlit state, and
the collimating lens is configured to emit the parallel light at a different emission angle depending on a position of the light emitter in the lit state.

2. The detection device according to claim 1, comprising a stage provided between the photodiodes and the collimating lens in a direction orthogonal to the substrate, wherein
an object to be detected is to be placed on the stage.

3. The detection device according to claim 1, wherein
the light emitters are configured to be sequentially brought into the lit state in detection periods, and
the photodiodes are each configured to sequentially output a detection signal corresponding to the position of the light emitter in the lit state in each of the detection periods.

4. The detection device according to claim 3, comprising an image processing circuit configured to generate one image by combining a plurality of images acquired in the respective detection periods, based the detection signals that have been output in the respective detection periods and information on the light emitters in the lit state in the respective detection periods.

5. The detection device according to claim 3, wherein an amount of shift of each of the images in the respective detection periods in plan view is a non-integer multiple of an arrangement pitch of the photodiodes.

6. The detection device according to claim 1, comprising a light distribution lens provided between the light emitters and the collimating lens.

7. The detection device according to claim 1, comprising a reference marker between the photodiodes and the collimating lens, wherein the reference marker has a first region having higher light transmittance and a second region having lower light transmittance than the first region.

8. The detection device according to claim 7, wherein, in plan view, the first region and the second region are arranged adjacent to each other in a first direction, and arranged adjacent to each other in a second direction orthogonal to the first direction.

9. The detection device according to claim 7, configured to detect an amount of shift of an image for each of the positions of the light emitters in the lit state, based on a detection signal of each of the photodiodes at a location overlapping the reference marker.

10. The detection device according to claim 1, comprising a light source that is located so as to face the photodiodes and comprises a plurality of light-emitting elements, wherein
the light emitters are the light-emitting elements.

11. The detection device according to claim 1, comprising a liquid crystal panel that is located so as to face the photodiodes and comprises a plurality of pixels, wherein
the light emitters are the pixels.
